(19) United States
(12) Patent Application Publication
(10) Pub. No.: US 2016/0056409 A1
(43) Pub. Date: Feb. 25, 2016

(54) ORGANIC EL ELEMENT AND METHOD FOR MANUFACTURING SAME

(71) Applicant: NATIONAL INSTITUTE FOR MATERIALS SCIENCE, Abaraki (JP)

(72) Inventors: Toshihide NABATAME, Tsukuba (JP); Kazuhito TSUKAGOSHI, Tsukuba (JP); Shinya AIKAWA, Tsukuba (JP)

(73) Assignee: National Institute for Materials Science, Ibaraki (JP)

(21) Appl. No.: 14/780,765

(22) PCT Filed: Mar. 28, 2014
(86) PCT No.: PCT/JP2014/059190

§ 371 Date: Sep. 28, 2015

(30) Foreign Application Priority Data
Mar. 28, 2013 (JP) 2013-067782
Mar. 28, 2013 (JP) 2013-067801
Mar. 28, 2013 (JP) 2013-068164

(51) Int. Cl. H01L 51/52; C23C 14/18; C23C 14/08; H01L 51/00; C23C 14/34

(52) U.S. Cl. CPC H01L 51/5234; H01L 51/5206; H01L 51/0021; C23C 14/3464; C23C 14/086; C23C 14/185

(57) ABSTRACT

Provided is an organic EL element which has excellent luminous efficiency by improving the cathode. An organic EL element which is configured of a cathode, an anode and one or more organic compound layers provided between the electrodes, and wherein the cathode is formed of a transparent conductive film that is formed on a glass substrate and is configured from an indium oxide compound and an element having a high work function, so that the cathode has a high work function matched to the HOMO of an organic hole transport layer among the organic compound layers. Consequently, holes can be easily injected from the cathode to the organic hole transport layer, and the present invention is therefore suitable for manufacturing an organic EL element having excellent luminous efficiency.

### TECHNICAL FIELD

The present invention claims the priority of Japanese Patent Application Nos. 2013-067782, 2013-067801 and 2013-068164 filed on Mar. 28, 2013, the contents thereof are incorporated herein by reference.

The present invention relates to an organic electroluminescence element (hereinafter, referred to as an organic EL element).

### BACKGROUND ART

Thin displays using organic EL elements are self-emitting flat panel displays, and are expected on the viewpoint of excellent properties such as low electric power consumption, wide view angle, fast response and needs for high luminance full colorization.

An organic EL element is constituted with an element structure of a cathode/two or more-layered organic compound layer/an anode, and a transparent conductive film is used for a cathode or an anode. As a double-layered organic compound layer, there is a layer composed of an organic hole transport layer and an organic light emitting layer, between the cathode and the anode, and the mechanism involved is such that the holes injected from the cathode and the electrons injected from the anode are recombined in the organic light emitting layer to form an excited state, and when the excited state returns to the ground state, light is emitted. For the purpose of efficiently injecting holes and electrons into the organic hole transport layer and the organic light emitting layer, respectively, examples of the electrode materials of the cathode and the anode include, respectively, ITO (Indium Tin Oxide) as a transparent conductive film having a high work function and an alkaline earth metal having a low work function.

In the organic EL element, the degradation of the injection efficiency of the holes is significantly suppressed by reducing the gap between the work function of the cathode and the highest occupied molecular orbital (HOMO) of the organic hole transport layer so as for the matching between the work function and the HOMO to be made satisfactory. For example, when as the organic hole transport layer, naphthyl phenyl benzidine (NPB: N,N′-bis-(1-naphthyl)-N,N′-diphenyl-1, 1-biphenyl 1-4,4′-diamine) is used, HOMO is situated at 5.7 eV and the work function of the cathode is desired to have this value. However, because the work function of ITO frequently used as the electrode material of the cathode is 4.5 to 4.7 eV, when holes are injected from ITO to the HOMO of the organic hole transport layer, the energy gap between ITO and the HOMO is large, and hence there has been a problem such that it is difficult to reduce the energy barrier in the cathode/organic hole transport layer interface, and consequently no sufficient injection efficiency of the holes is obtained.

In order to solve these problems, PATENT LITERATURE 1 discloses the use, as a cathode, of a metal such as Ni, Pd, Ir, Pt or Au which has a higher work function than ITO. However, this case requires a transparent conductive film to be used for the anode, and involves a problem that the restrictions imposed on the anode materials are severe.

In order to increase the work function of ITO while the transparency and conductivity of the cathode is being maintained, there have been reported attempts to increase the oxygen concentration of the ITO film by using the following methods: a method in which the ITO film is subjected to UV-ozone oxidation (NON PATENT LITERATURE 1); a method in which the ITO film is subjected to inductively coupled plasma oxygen treatment (NON PATENT LITERATURE 2); a method in which the ITO film is treated with a KrF pulse laser (NON PATENT LITERATURE 3); and there has also been reported a method for increasing the oxygen concentration of the ITO film by doping V, Hf or Zr element into the ITO film and by forming the oxide of the doped element (NON PATENT LITERATURE 4).

However, the techniques for increasing the oxygen concentration in the ITO film by the oxidation methods described in the foregoing literature and the like complicate the processing process of the organic EL element, and also involve a problem that the oxygen concentration in the ITO film is heavily affected by the atmosphere conditions of the processing process. Actually, the present inventors have found that when the ITO film is exposed to a 3% H₂ atmosphere, even at a low temperature of 300° C., the effective work function is easily decreased by about 0.8 eV. The method for increasing the oxygen concentration by the oxidation of the element doped into the ITO film increases the work function with the increase of the addition amount of the doped element, but increases the resistance by four orders of magnitude in a trade-off relation with the work function, so as to cause a problem that almost no addition amount region meets a high work function and a small resistance. The method for increasing the work function of the ITO film by a thermal oxidation requires a high temperature of 300° C. or higher, so as to impose a severe restriction on the fabrication process of the organic EL element.

There has also been reported a method for introducing a layer having a higher work function than the work function of ITO between the ITO cathode and the organic compound layer. For example, the introduction of the following layers has been reported: a 15-nm-thick doped ITO layer or a doped CuPc (Copper Phthalocyanine) layer having a higher work function than the work function of the ITO layer between the ITO and the NPB of the organic compound layer (NON PATENT LITERATURE 4), and a 4-nm-thick In₂O₃:Pt,W layer (NON PATENT LITERATURE 5). In order to increase the work function of the ITO film, the formation of the following films on the ITO film has been reported: a 2.5-nm-thick Ni film (NON PATENT LITERATURE 2), and a 1.4-nm-thick Au or Pt film (NON PATENT LITERATURE 6).

However, the methods for introducing a layer having a higher work function than the work function of ITO between the ITO film and the organic compound layer, described in the foregoing literature and the like involve the following problems: considerable restrictions are imposed on the processing process of the organic EL element because the layer having a higher work function than the work function of ITO requires the use of an etching material different from ITO in the electrode processing based on wet etching; and in the case where the layer having a higher work function than the work function of ITO is made of a metal, the transmittance for visible light is decreased.

### CITATION LIST

### Patent Literature

PATENT LITERATURE 1: JP-A-2000-133464

### Non Patent Literature

NON PATENT LITERATURE 1: Journal of APPLIED PHYSICS 86, 1688(1999).
NON PATENT LITERATURE 2: Journal of APPLIED PHYSICS 95, 586(2004).
NON PATENT LITERATURE 3: Journal of Vacuum Science Technology A 24, 1866(2006).
NON PATENT LITERATURE 4: Journal of APPLIED PHYSICS 99, 114515(2006).
NON PATENT LITERATURE 5: ELECTRONICS LETTERS 44, 20081318(2008).
NON PATENT LITERATURE 6: Journal of Vacuum Science Technology A 17, 1773(1999).

### SUMMARY OF INVENTION

### Technical Problem

The present invention has been achieved in view of such circumstances as described above, and an object of the present invention is to provide an organic EL element having solved the above-described problems and a method for manufacturing the same, by using a cathode formed of a transparent conductive film constituted with an indium oxide compound and an element having a high work function.

### Solution to Problem

According to an aspect of the present invention, there is provided an organic EL element including: a transparent substrate; a cathode formed on the transparent substrate; a one or more-layered organic compound layer formed on the cathode; and an anode formed on the organic compound layer, wherein the cathode is a transparent conductive film including an indium oxide compound and a noble metal element-containing conductive oxide.

Here, the transparent electrode film may include a first transparent conductive film being disposed on the side of the transparent substrate, including the indium oxide compound but not including the noble metal element; a second transparent conductive film being disposed on the side of the organic compound layer and including the indium oxide compound and the noble metal element.

The addition amount of the noble metal element of the noble metal element-containing conductive oxide may fall within a range larger than 0 at. % and smaller than 50 at. % in relation to the total amount of the noble metal element and the indium element of the indium oxide compound.

The noble metal element-containing conductive oxide may be a conductive oxide composed of one or a combination of two or more selected from the group consisting of PtOₓ, IrOₓ and RuOₓ.

The noble metal element-containing conductive oxide may be SrRuOₓ.

The indium oxide compound may be represented by the chemical formula, InₓMe₁₋ₓO_{y}, wherein Me is one or more elements selected from the group consisting of the elements of the Group IVa, Group Va, Group IVb and Group Vb, and 0<x<0.5 and 1.0<y<2.0.

The indium oxide compound may be one or more compounds selected from the group consisting of InₓSn₁₋ₓO_{y} (1.25<y<1.5), InₓZn₁₋ₓO_{y} (1.25<y<1.5), InₓW₁₋ₓO_{y} (1.5<y<2.25) and InₓSi₁₋ₓO_{y} (1.5<y<1.75), wherein 0<x<0.5.

According to a second aspect of the present invention, there is provided a method for manufacturing the organic EL element, the method forming the transparent conductive film by a co-sputtering method, wherein the sputtering power ratio between the indium oxide compound and the noble metal-containing conductive oxide is regulated, and thus the transparent conductive film controlled in the composition ratio between the indium oxide compound and the noble metal-containing conductive oxide is formed.

There is also provided a method for manufacturing the organic EL element, wherein the transparent conductive film is formed by using a method of co-sputtering the indium oxide compound and the metal of the noble metal element, and then the oxygen composition ratio of the transparent conductive film is controlled by subjecting the transparent conductive film to ozone and/or plasma oxidation treatment.

According to a third aspect of the present invention, there is provided an organic EL element, wherein the transparent electrode film includes a first transparent conductive film being disposed on the side of the transparent substrate, and including the indium oxide compound, and a second transparent conductive film being disposed on the side of the organic compound layer, and including indium oxide and the noble metal element-containing conductive oxide.

The second transparent conductive film may be an amorphous structure.

The thickness of the second transparent conductive film may be 4 nm or less.

The addition amount of the noble metal element of the noble metal element-containing conductive oxide may fall within a range larger than 20 at. % and smaller than 70 at. % in relation to the total amount of the noble metal element and the indium element in the indium oxide.

The noble metal element-containing conductive oxide may be a conductive oxide composed of one or a combination of two or more selected from the group consisting of PtOₓ, IrOₓ and RuOₓ.

The noble metal element-containing conductive oxide may be SrRuOₓ.

The indium oxide compound may be represented by the chemical formula, InₓMe₁₋ₓO_{y}, wherein Me is one or more elements selected from the group consisting of the elements of the Group IVa, Group Va, Group IVb and Group Vb, and 0<x<0.5 and 1.0<y<2.0.

The indium oxide compound may be one or more compounds selected from the group consisting of InₓSn₁₋ₓO_{y} (1.25<y<1.5), InₓZn₁₋ₓO_{y} (1.25<y<1.5), InₓW₁₋ₓO_{y} (1.5<y<2.25) and InₓSi₁₋ₓO_{y} (1.5<y<1.75), wherein 0<x<0.5.

According to a fourth aspect of the present invention, there is provided a method for manufacturing the organic EL element, the method forming the second transparent conductive film by a co-sputtering method, wherein the sputtering power ratio between the indium oxide and the noble metal element is regulated, and thus the second transparent conductive film controlled in the composition ratio between the indium oxide and the noble metal element-containing conductive oxide is formed.

According to a fifth aspect of the present invention, there is provided an organic EL element including: a transparent substrate; a cathode formed on the transparent substrate; a one or more-layered organic compound layer formed on the cathode; and an anode formed on the organic compound layer, wherein the cathode includes a high work function layer formed of a material having a work function higher than 5 eV and having a thickness of 0.6 nm or more and 1.2 nm or less.

There is also provided an organic EL element including: a transparent substrate; a cathode formed on the transparent substrate; a one or more-layered organic compound layer formed on the cathode; and an anode formed on the organic compound layer, wherein the cathode includes a plurality of particles formed of a material having a work function higher than 5 eV.

The particle sizes of the particles may be 0.6 nm or more and 2 nm or less. The material having a work function higher than 5 eV may be one material or a combination of two or more materials selected from the group consisting of PtOₓ, IrOₓ and RuOₓ.

The material having a work function higher than 5 eV may be one element or an alloy of two or more elements selected from the group consisting of Pt, Ir, Pd, Ni, Au and Co.

The material of the cathode may be the indium oxide compound represented by InₓMe₁₋ₓO_{y}, wherein Me is one or more elements selected from the group consisting of the elements of the Group IVa, Group Va, Group IVb and Group Vb, and 0<x<0.5 and 1.0<y<2.0.

The indium oxide compound may be one or more compounds selected from the group consisting of InₓSn₁₋ₓO_{y} (1.25<y<1.5), InₓZn₁₋ₓO_{y} (1.25<y<1.5), InₓW₁₋ₓO_{y} (1.5<y<2.25) and InₓSi₁₋ₓO_{y} (1.5<y<1.75), wherein 0<x<0.5.

According to a sixth aspect of the present invention, there is provided an organic EL element including: a transparent substrate; a cathode formed on the transparent substrate; a one or more-layered organic compound layer formed on the cathode; and an anode formed on the organic compound layer, wherein the cathode includes a transparent conductive film including an indium oxide compound and a metal having a high work function; and the metal being included in the transparent conductive film and having a high work function has a concentration gradient from the side of the transparent substrate toward the side of the organic compound.

The concentration of the metal being included in the transparent conductive film and having a high work function may be higher in the region of the organic compound layer than in the region on the side of the transparent substrate.

The metal having a high work function may be one or more elements selected from Pt, Ir, Pd, Ni, Ru, Au and Co.

The concentration of the metal having a high work function may be 60 at. % or more and 100 at. % or less in the region on the side of the organic compound layer.

The indium oxide compound may be represented by InₓMe₁₋ₓO_{y}, wherein Me is one or more elements selected from the group consisting of the elements of the Group IVa, Group Va, Group IVb and Group Vb, and 0<x<0.5 and 1.0<y<2.0.

The indium oxide compound may be one or more compounds selected from the group consisting of InₓSn₁₋ₓO_{y} (1.25<y<1.5), InₓZn₁₋ₓO_{y} (1.25<y<1.5), InₓW₁₋ₓO_{y} (1.5<y<2.25) and InₓSi₁₋ₓO_{y} (1.5<y<1.75), wherein 0<x<0.5.

According to a seventh aspect of the present invention, there is provided a method for manufacturing the organic EL element, the method forming the transparent conductive film by a sputtering method, wherein the sputtering power ratio between the indium oxide compound and the metal having a high work function is regulated, and thus the transparent conductive film having the concentration gradient of the metal having a high work function is formed.

There is also provided a method for manufacturing the organic EL element, the method forming the transparent conductive film by a sputtering method, wherein a plurality of targets varied in the composition ratio between the indium oxide compound and the metal having a high work function are arranged, the transparent conductive film is formed by using a sputtering method consecutively using the plurality of targets, and thus the transparent conductive film having the concentration gradient of the metal having a high work function is formed.

### Advantageous Effects of Invention

According to the present invention, the work function of the transparent conductive film of the cathode can be made high without remarkably decreasing the conductivity and the transmittance for visible light, and hence an organic EL element having excellent luminous efficiency and an method for manufacturing the same can be provided.

Other objects, features and advantages of the present invention will be apparent from the description of the following examples of the present invention with reference to the accompanying drawings.

### BRIEF DESCRIPTION OF DRAWINGS

FIG. 1 is a diagram conceptually illustrating the structure of the organic EL element of an example of the present invention.

FIG. 2A is a diagram illustrating a method for fabricating an ITO film.

FIG. 2B is a diagram illustrating a method for fabricating an ITO:IrOₓ film by a method for co-sputtering ITO and IrOₓ.

FIG. 3A is a diagram illustrating a method for fabricating an ITO:PtOₓ film by a method for co-sputtering ITO and Pt.

FIG. 3B is a diagram illustrating an ozone-oxygen treatment method of an ITO:PtOₓ film.

FIG. 4 is a graph showing the variations of the effective work functions of the transparent conductive films constituted with an indium oxide compound and a noble metal-containing conductive oxide.

FIG. 5 is a graph showing the variations of the effective work functions of an ITO film and an ITO:IrOₓ film against the 3% H₂ reduction treatment temperature.

FIG. 6 is a graph showing the transmission spectra of an ITO film and an ITO:IrOₓ film.

FIG. 7 is a diagram conceptually illustrating the structure of an organic EL element of an example of the present invention.

FIG. 8 is a graph showing the X-ray diffraction spectra for the surfaces of cathodes.

FIG. 9 shows the root mean square (RMS) roughness images for the surfaces of the cathodes as measured with an atomic force microscope.

FIG. 10 shows the transmission spectra of an ITO films and an ITO/IRO film.

FIG. 11 is a diagram conceptually illustrating the structure of an organic EL element of an example of the present invention.

FIG. 12 shows a diagram conceptually illustrating the structure of an organic EL element of an example of the present invention.

FIG. 13 is a graph showing the variation of the effective work function of an ITO/RuOₓ film against the thickness of the RuOₓ film.

FIG. 14 is a graph showing the variations of the effective work functions of the ITO film and the ITO/RuOₓ (1.2 nm) film against the 3% H₂ reduction treatment temperature.

FIG. 15 is a graph showing the variations of the transmission spectra of an ITO film and an ITO/RuOₓ(1.2 nm) film.

FIG. 16 is a graph showing the variation of the effective work function of an ITO/Au dots against the diameter of the Au dots.

FIG. 17 is a diagram conceptually illustrating the structure of an organic EL element of an example of the present invention.

FIG. 18 shows a diagram schematically illustrating the structure of an organic EL element having a cathode provided with a transparent conductive film formed of an indium oxide compound and a metal having a high work function, and a graph showing the concentration distribution of the metal having a high work function.

FIG. 19 is a graph showing the Pt concentration distribution of an ITO:Pt film against the position in the direction perpendicular to the film surface.

FIG. 20 is a graph showing the transmission spectra of an ITO:Pt film, an ITO film and a glass substrate.

FIG. 21 is a graph showing the effective work function of an ITO:Pt film against the Pt concentration of an ITO:Pt film determined with an ITO:Pt electrode SiO₂ capacitor.

FIG. 22 is a diagram schematically illustrating a sputtering method in which sputtering targets are consecutively arranged.

### DESCRIPTION OF EMBODIMENTS

Hereinafter, with reference to the accompanying drawings, the organic EL element according to the embodiment of the present invention and the method for manufacturing the same are described. It is to be noted that in all the following drawings, the dimensions, the proportions and the like of the constituent elements are appropriately modified for the purpose of making the drawings easier to see.

In the present invention, as the cathode of the organic EL element, a transparent conductive film constituted with an indium oxide compound and an element having a high work function is formed, and thus, the work function of the cathode can be made high. In the transparent conductive film, the addition amount of the element having a high work function, falling within a range larger than 0 at. % and smaller than 50 at. % in relation to the In element of the indium oxide compound preferably allows the degradation of the transmission property for visible light to be suppressed. The increase of the addition amount of the element having a high work function in the transparent conductive film, more on the side of the organic compound layer than on the side of the transparent substrate, preferably allows the degradation of the transmission property for visible light to be suppressed, even when the addition amount of the element having a high work function is 50 at. % or more in relation to the In element of the indium oxide compound.

From the view of the structural stability as the cathode, Me of the indium oxide compound, InₓMe₁₋ₓO_{y}, is preferably the elements of the Group IVa, Group Va, Group IVb and Group Vb. Because of being required to be a low resistance conductor and to have a high transmittance in the visible light region, x preferably falls within a range larger than 0 and smaller than 0.5. In the case of the Group IVa, Group Va, Group IVb and Group Vb, the value of y preferably falls within a range larger than 1.0 and smaller than 2.0. In particular, the indium oxide compounds such as InₓSn₁₋ₓO_{y}, InₓZn₁₋ₓO_{y}, InₓW₁₋ₓO_{y} and InₓSi₁₋ₓO_{y} are excellent in the compatibility with the element having a high work function, and are suitable for maintaining the stable oxygen composition proportion hardly affected by the oxidation-reduction atmosphere of the process.

### EXAMPLES

Hereinafter, the present invention is described specifically by way of Examples; however, the present invention is not limited to these Examples.

### Example 1

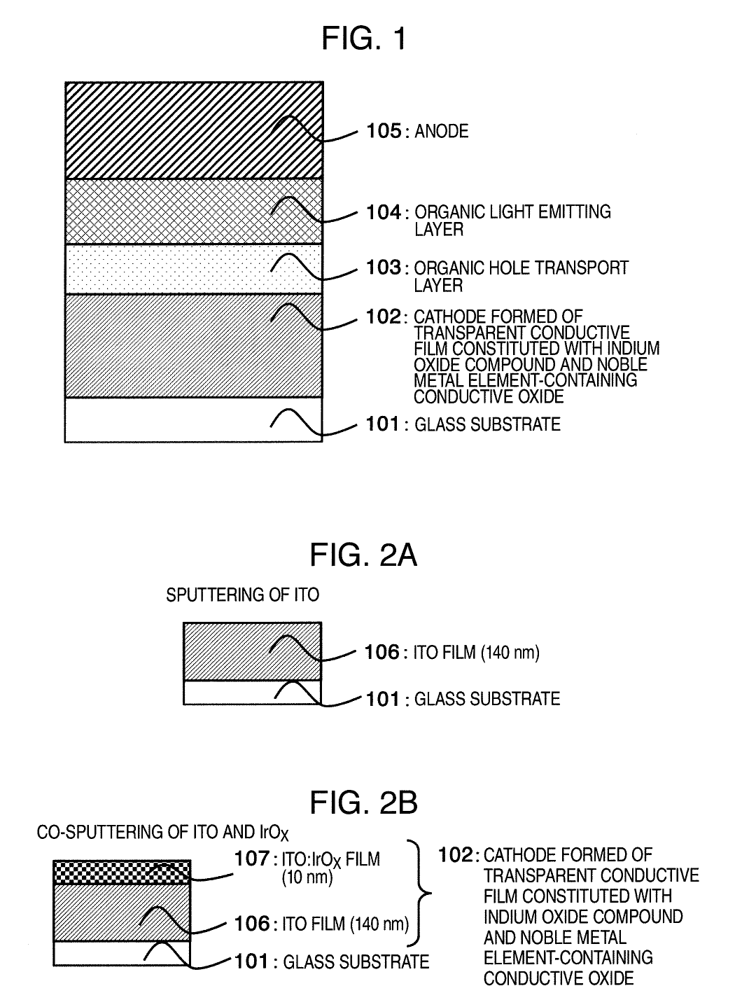

FIG. 1 shows the structure of the organic EL element of an example of the present invention. On a glass substrate 101 to be used as a transparent substrate, a cathode 102 as a transparent conductive film constituted with an indium oxide compound and a noble metal-containing conductive oxide, an organic hole transport layer 103, an organic light emitting layer 104 (the organic hole transport layer 103 and the organic light emitting layer 104 are collectively referred to as an organic compound layer), and an anode 105 are formed in this order. The noble metal-containing conductive oxide is a conductor having a low resistance, and the addition of the noble metal-containing conductive oxide to the indium oxide compound does not cause an adverse effect to increase the resistance. Because the conductive oxide is an oxide, there is no possibility that the addition of the conductive oxide robs the indium oxide compound of oxygen to make it difficult to control the oxygen composition proportion. Moreover, the conductive oxide has a higher value of the effective work function as compared with the value of the effective work function (4.7 eV) of ITO, a typical indium oxide compound among the indium oxide compounds, and is expected to display a function to increase the work function of the transparent conductive film.

In the fabrication of the organic EL element, there was formed as the cathode, a 150-nm-thick ITO (ITO:IrOₓ) film, on the glass substrate, to which a conductive oxide including the noble metal element of IrOₓ was added, by a co-sputtering method using an ITO (In_{0.9}Sn_{0.1}O) target and an IrOₓ target in an Ar gas atmosphere. The composition ratio between ITO and IrOₓ were regulated by setting the sputtering power of the ITO side at a constant value of 150 W and by varying the sputtering power of the IrOₓ side from 10 W to 150 W, and the concentration of the Ir element (Ir/(In+Ir)) was controlled so as to fall within a range smaller than 50 at. % in relation to the total amount of the indium element and the iridium element. In the case of an ITP film including IrOₓ added thereto and having a constant composition ratio of IrOₓ/ITO, fabricated by a co-sputtering method from the beginning, and in the case where as shown in FIGS. 2A and 2B, the ITO film of FIG. 2A was formed in a thickness of 140 mm, an ITO film of FIG. 2B including IrOₓ added thereto was formed in a thickness of 10 mm by the co-sputtering method, when the Ir/In composition ratio in the ITO film including IrOₓ added thereto were the same, the effective work functions of these cases exhibited almost the same values. Successively, as the organic hole transport layer, a film of naphthyl phenyl benzidine (NPB) was formed in a thickness of 40 nm by vacuum vapor deposition, and on the resulting film, as an organic light emitting layer, a film of aluminum quinolinol complex (Alq3) was formed in a thickness of 40 nm by vacuum vapor deposition. Finally, a film of a magnesium-silver alloy (MgAg) was formed in a thickness of 40 nm by vacuum vapor deposition to fabricate an organic EL element.

In order to determine the effective work function of the ITO:IrOₓ film, the following capacitor was fabricated. A P-type Si substrate was heat treated in an oxygen atmosphere at 900° C. to fabricate a SiO₂ film. The thickness of the SiO₂ film was regulated by varying the heat treatment time so as to be 6, 8 or 12 nm. Successively, by using the co-sputtering method based on the ITO target and the IrOₓ target, a 150-nm-thick ITO:IrOₓ gate electrode was fabricated by a lift-off process to fabricate a capacitor. By varying the sputtering power of each of the targets of the co-sputtering, the Ir concentration of the ITO:IrOₓ film was controlled within a range of 0 to 50 at. % (it is to be noted that the at. % as referred to herein means the concentration of the iridium element (Ir/(In+Ir)) in relation to the total amount of the indium element and the iridium element). Successively, by the capacity (C)-voltage (V) measurement, the flat band voltage (Vfb) was determined, and from the variation of the Vfb against the SiO₂ thickness, the effective work function was calculated. FIG. 4 shows the variations of the effective work function of the ITO:IrOₓ electrode having an Ir concentration of 40 at. %. The ordinate represents the value obtained by subtracting the value of the effective work function obtained from the ITO/SiO₂/p-Si capacitor fabricated as a reference. It has been found that the addition of IrOₓ allows the effective work function to achieve a large increase of approximately 0.8 eV.

FIG. 4 also shows the variations (namely, the values obtained by subtracting the effective work functions determined from the corresponding reference capacitors using the indium oxide compound film) of the effective work functions measured in the case where IZO and IWO were used as described later as the indium oxide compounds in addition to ITO, and RuOₓ, PtOₓ and SrRuOₓ were used as the noble metal oxides in addition to IrOₓ. The concentrations of the noble metal elements other than iridium were also defined in the same way of thinking as for the above-described concentration of the iridium element.

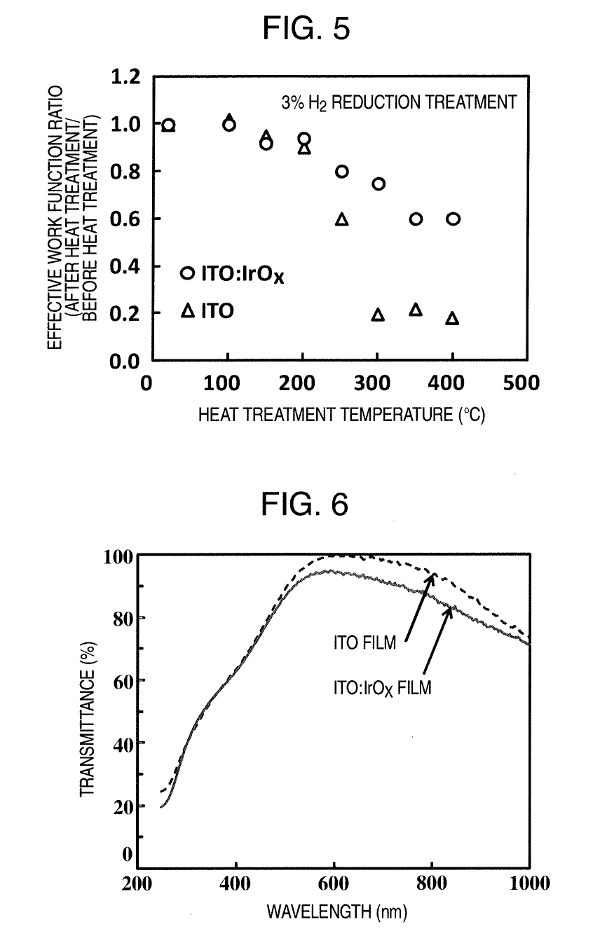

FIG. 5 shows a graph showing the variations of the effective work functions, calculated from the SiO₂ capacitors when an ITO film and an ITO:IrOₓ film were subjected to reduction treatment from 100° C. to 400° C. at intervals of 50° C. under a flow of 100 sccm of 3% H₂ gas. The ordinate represents the ratio of the effective work function after the heat treatment, namely, the value obtained by dividing the value of the effective work function after the heat treatment by the value of the effective work function before the heat treatment. The effective work function of the ITO film decreased steeply from 250° C., and decreased at 300° C. by approximately 80% from the value before the heat treatment. The value was the same even when the temperature was further increased, and hence the decrease was saturated at 300° C. The major cause of the decrease of the effective work function is considered to be the elimination of oxygen from the ITO film due to the reduction treatment. On the other hand, the effective work function of the ITO:IrOₓ film exhibited a slow decrease with the increase of the temperature; however, even at 400° C., the decrease of the work function was found to be suppressed to approximately 40% of the value of the work function before the heat treatment. When compared with the ITO film at 300° C., the decrease rate of the effective work function is smaller by approximately 60%. This is probably because the addition of IrOₓ suppressed the elimination of oxygen from the ITO:IrOₓ film.

FIG. 6 shows the variation of the transmission spectra of the ITO film and the ITO:IrOₓ film against the wavelength. The ordinate represents the difference obtained by subtracting the transmission spectrum of only the glass substrate. The profile of the transmittance of the ITO:IrOₓ film of the present invention against the wavelength was somewhat lower as compared with the profile of the transmittance of the ITO film; however, the value of the transmittance at 600 nm in the visible light region exhibited 90%, to cause no problem.

SiO₂ capacitors were fabricated in which the IZO:IrOₓ electrode and the IWO:IrOₓ electrode were formed by using IZO (In_{0.95}Zn_{0.05}O) and IWO (In_{0.99}W_{0.01}O) as targets in place of ITO, and by the co-sputtering method using these targets with the IrOₓ target. FIG. 4 shows the variations of the effective work functions of the IZO:IrOₓ electrode and the IWO:IrOₓ electrode each having an Ir concentration of 40 at. %. Similarly to the case of ITO:IrOₓ, high effective work function values of approximately 0.7 eV were obtained.

Moreover, six types of transparent conductive films (ITO:RuOₓ, IZO:RuOₓ, IWO:RuOₓ, ITO:SrRuOₓ, IZO:SrRuOₓ and IWO:SrRuOₓ) were fabricated by using the RuOₓ and SrRuOₓ targets in place of the IrOₓ target, and by using the co-sputtering method using these targets in combination with the targets of ITO, IZO and IWO. The variations of the effective work functions of the six types of electrodes were collectively shown in FIG. 4. As can be seen from FIG. 4, variations (increases) smaller by approximately 0.1 to 0.2 eV for RuOₓ and approximately 0.2 to 0.3 eV for SrRuOₓ were found as compared with the case of IrOₓ, but higher effective work function values were exhibited as compared with ITO alone. This is probably because the order of the magnitudes of the work functions of noble metal-containing conductive oxides is represented by the order of SrRuOₓ<RuOₓ,PtOₓ<IrOₓ, and this order affected the work functions.

### Example 2

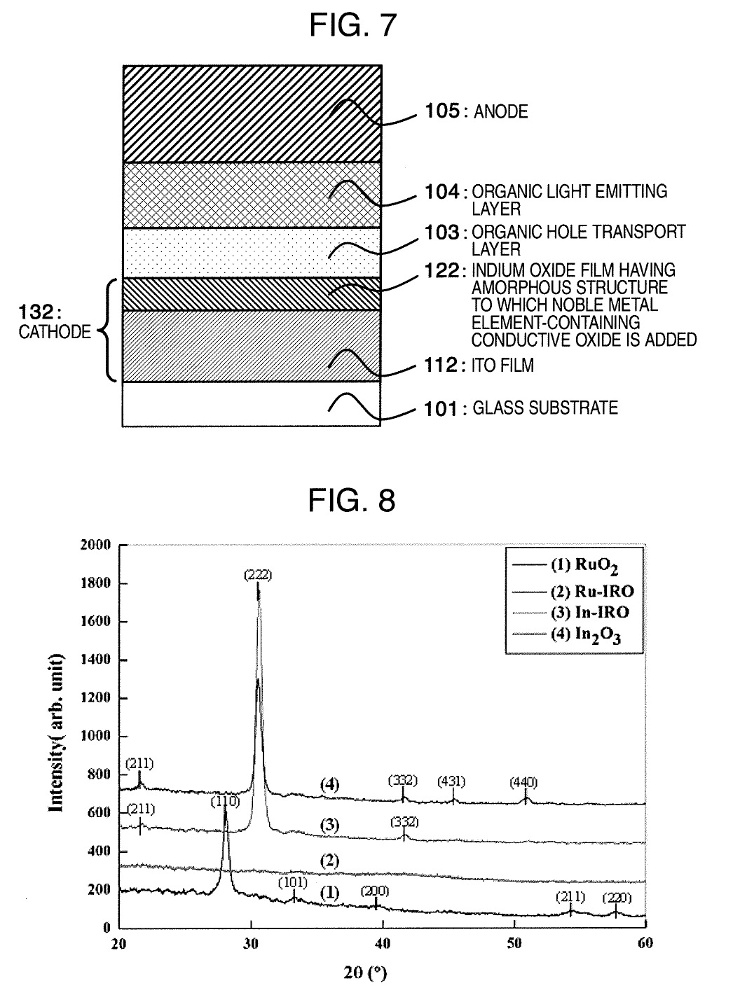

FIG. 7 shows the structure of the organic EL element of an example of the present invention, including an cathode 132 as a transparent conductive film, constituted with an ITO film 112 constituted with an indium oxide compound on a glass substrate 101 and an indium oxide film 122 having an amorphous structure including a noble metal element-containing conductive oxide as added thereto. The organic EL element structure is constituted in the same manner as in FIG. 1 except for the cathode 132 as a transparent conductive film. The adoption of the amorphous structure results in a film excellent in smoothness, the resulting smoothness allows the indium oxide film 122 having an amorphous structure including a noble metal element-containing conductive oxide as added thereto to suppress the light scattering in the interface involving the indium oxide film 122, and thus allows light to more easily transmits through the indium oxide film 122. The thickness of the indium oxide film 122 having an amorphous structure including a noble metal element-containing conductive oxide as added thereto is preferably 4 nm or less. The addition amount of the noble metal of the noble metal element-containing conductive oxide is preferably regulated so as for the work function of the indium oxide film having an amorphous structure including the noble metal element-containing conductive oxide as added thereto to be 5 eV or more.

In the fabrication of the organic EL element, there was formed as an cathode an indium film (IRO film) having an amorphous structure, including RuOₓ as added thereto by a process in which there was formed, on the glass substrate, an ITO film by using an ITO (In_{0.9}Sn_{0.1}O) target, and subsequently RuOₓ was added by a co-sputtering method in an oxygen/Ar gas atmosphere, using an In₂O₃ target and a Ru target. In this case, the sputtering power for the Ru target was regulated in such a way that the effective work function of the IRO film was controlled to be 5 eV or more. In order to allow the IRO film to have an amorphous structure, the concentration of the Ru element (Ru/(In+Ru)) in relation to the total amount of the In element and the Ru element in the IRO film is preferably set to be larger than 20 at. % and smaller than 70 at. %.

In the IRO film (Ru-IRO) having a concentration of the Ru element, (Ru/(In+Ru)), of 62 at. %, in the case where thickness thereof was 3 nm, the effective work function was regulated to be 5.72 eV and the resistance value was 1.6×10⁻⁴ (Ω·cm). FIG. 8 shows the X-ray diffraction spectrum of the IRO film. In the case of the formation of the Ru-IRO film, the diffraction intensity against the incidence angle of X-ray on the abscissa is smooth and has no peak to indicate that the film has an amorphous structure (FIG. 8, (2)). In contrast to this, for each of In₂O₃ ((FIG. 8, (4)), RuO₂ (FIG. 8, (1)), and In-IRO (Ru/(In+Ru)=5 at. %) (FIG. 8, (3)), an X-ray diffraction intensity peak is present to show that crystal structure is involved.

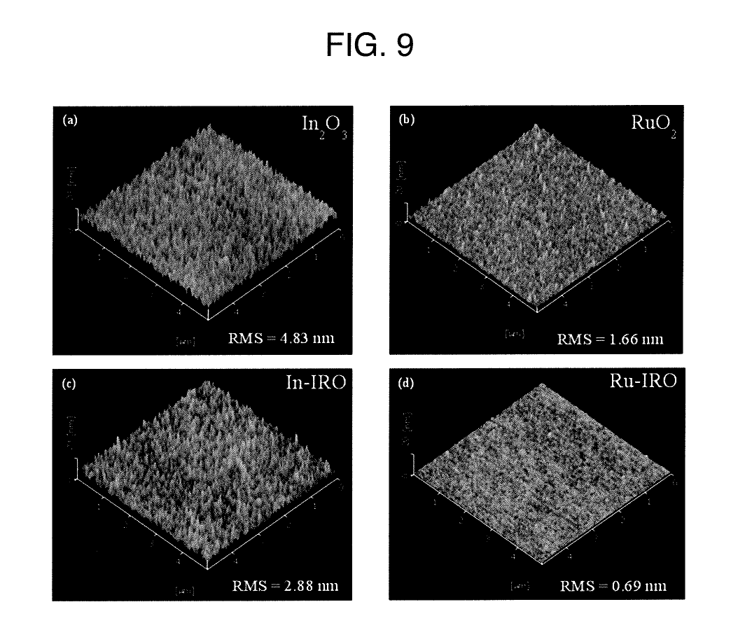

FIG. 9 shows the root mean square (RMS) roughness images for the surfaces of the cathodes as measured with an atomic force microscope. The Ru-IRO (FIG. 9, (d)) having amorphous structure has an RMS value of 0.69 nm to show that the case of Ru-IRO film is higher in flatness than the other cases.

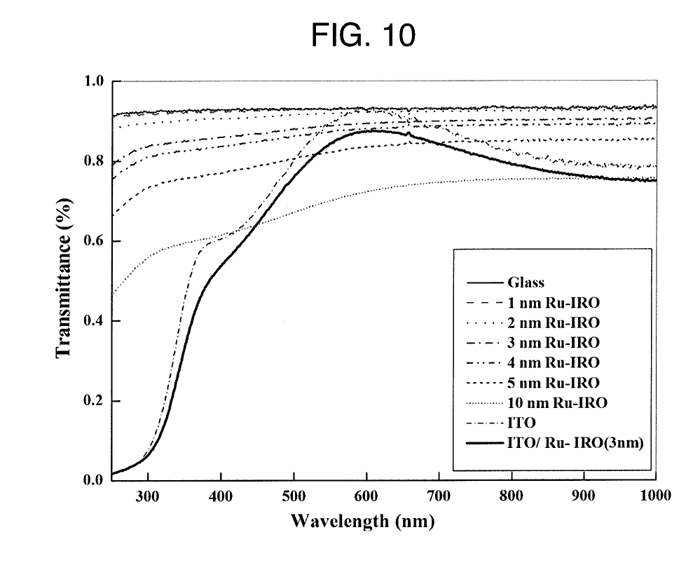

A sample was fabricated in which after a 3-nm-thick Ru-IRO film was formed on a glass substrate, a 150-nm-thick ITO film was formed. For comparison, the following samples were fabricated: a 150-nm-thick ITO film formed on a glass substrate; and 1, 2, 3, 4, 5 and 10-nm-thick Ru-IRO films each formed on a glass substrate. FIG. 10 shows the variation of the transmission spectra against the wavelength in the case of only the glass substrate, and in the cases of the individual fabricated samples. The profile (FIG. 10, ITO/Ru-IRO (3 nm)) of the transmittance of the ITO/Ru-IRO (3 nm) film of the present invention against the wavelength is somewhat lower than the profile of the ITO film (FIG. 10, ITO); however, the value of the transmittance at 600 nm in the visible light region exhibits 80%, to cause no problem.

When the cathode 132 as a transparent conductive film was fabricated by a process in which after the formation of the ITO film 112 constituted with an indium oxide compound, the indium oxide film 122 having an amorphous structure, including a noble metal element-containing conductive oxide as added thereto was formed so as for the thickness thereof to be 4 nm or less, the transmittance at 600 nm in the visible light region was found to be so high as causing no problems, not only in the case where the concentration of the noble metal in relation to the total amount of the In element and the noble metal element in the indium oxide film 122 having an amorphous structure, including the noble metal element-containing conductive oxide as added thereto fell within a range smaller than 50 at. % but also in the case where the concentration of the noble metal fell within a range of 50 at. % or more.

### Example 3

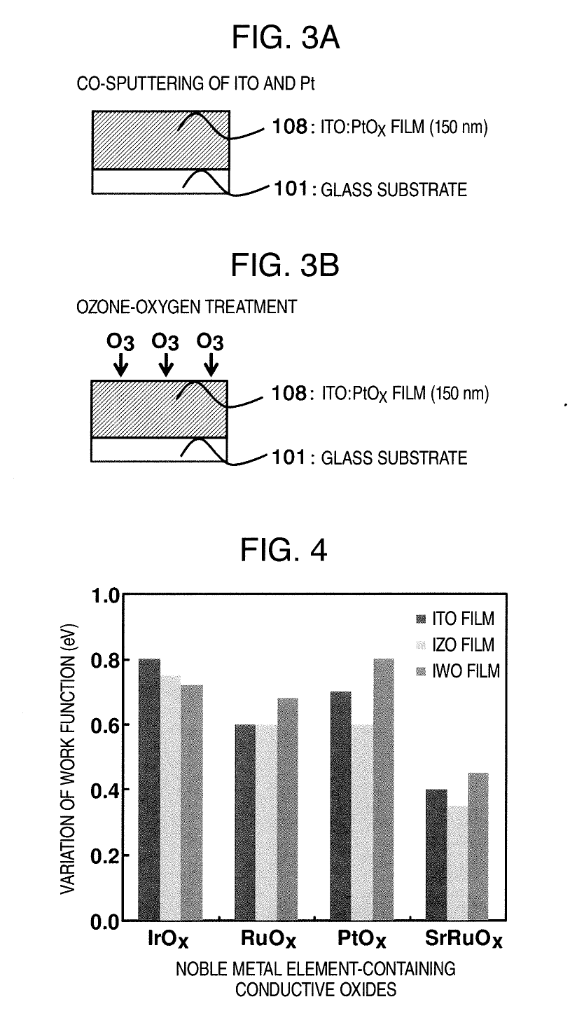

The third example of the present invention is described with reference to FIG. 3A and FIG. 3B. In the present example, the members other than the transparent conductive film are the same as those in the first example, and accordingly, only the method for manufacturing the transparent conductive film is shown in FIG. 3A and FIG. 3B. As shown in FIG. 3A, an ITO (ITO:PtOₓ) film including PtOₓ added thereto was formed on a glass substrate in a thickness of 150 nm by a co-sputtering method using an ITO target and a Pt target under introduction of oxygen/Ar gas, The metal Pt is well known as a hardly oxidizable material, and also known as a material including dissolved oxygen, and has an effect to increase the work function with the aid of oxygen having a high electronegativity. As shown in FIG. 3B, in order to further increase the dissolved oxygen in the ITO:PtOₓ film, ozone gas having an ozone concentration (O₃/(O₃+O₂)) of 80% was introduced from an ozone generator into a pressure-reduced chamber including the ITO:PtOₓ film placed therein, and the ITO:PtOₓ film was subjected to an ozone-oxygen treatment in a temperature range from room temperature to 200° C. In addition to the ozone-oxygen treatment, a similar effect can be obtained by placing the ITO:PtOₓ film in a vacuum chamber and subjecting the film concerned to a plasma-oxygen treatment with the aid of excitation with 100 W to 1.5 kW plasma. Successively, a 40-nm-thick film of naphthyl phenyl benzidine (NPB) was formed as an organic hole transport layer by vacuum vapor deposition, a 40-nm-thick film of aluminum quinolinole complex (Alq3) was formed thereover as an organic light emitting layer by vacuum vapor deposition, and finally a 40-nm-thick film of magnesium-silver alloy (MgAg) was formed by vacuum vapor deposition to fabricate an organic EL element. In FIGS. 3A and 3B, a case of ITO as the indium oxide is shown, but, of course, IZO and IWO can be used in addition to ITO. The effective work functions of the ITO:PtOₓ, IZO:PtOₓ and IWO:PtOₓ films were determined by fabricating SiO₂ capacitors in the same manner as in Example 1. FIG. 4 shows the data for the cases where the Pt concentration was 40 at. %. Each of these films exhibited a value of the effective work function higher by 0.6 eV or more as compared with the value of the ITO film; in particular, the highest effect was exhibited in the case of IWO:PtOₓ. These data shown in FIG. 4 are the measurement results for the films subjected to ozone-oxygen treatment; under the same dissolved oxygen concentration, similar results can also be obtained by performing plasma oxygen treatment.

In the case of the conductive oxide composed of a combination of two or more of IrOₓ, RuOₓ and PtOₓ, the bonding force between oxygen and each of the metals is increased, and consequently there occurs an effect to provide a high value of the effective work function from the low concentration.

### Example 4

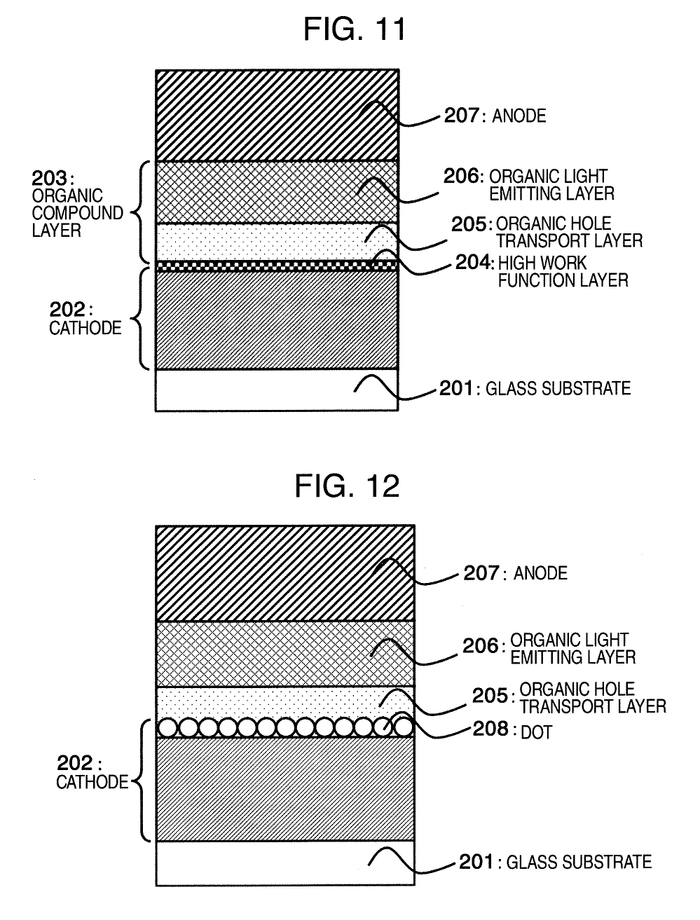

FIG. 11 shows the structure of an example of the organic EL element of the present invention. The organic EL element structure is constituted by forming the following members on a glass substrate 201 used as a transparent substrate in the described order: a cathode 202 as a transparent conductive film including a high work function layer 204, a one or more organic compound layer 203 (composed of an organic hole transport layer 205 and an organic light emitting layer 206), and an anode 207.

A 150-nm-thick ITO film was formed on the glass substrate by a 150-W high-frequency magnetron sputtering method using the ITO (In_{0.9}Sn_{0.1}O) target in an Ar gas atmosphere, successively a high work function layer of RuOₓ was formed by a 30-W high-frequency magnetron sputtering method using a RuOₓ target in an oxygen/Ar atmosphere, and consequently a cathode was formed. The effective work function of RuOₓ exhibits a high value of 5.5 eV as compared with 4.7 eV of the Ru metal. This is the effect of oxygen having a high electronegativity. On the same reason, IrOₓ and PtOₓ including dissolved oxygen have high effective work function values as compared with Ir and Pt, respectively. By varying the sputtering time under the conditions of the small film formation rate set by increasing the distance between the substrate and the target, the thickness of the RuOₓ film was regulated within a range from 0.6 to 1.2 nm.

Successively, a 40-nm-thick film of naphthyl phenyl benzidine (NPB) was formed as an organic hole transport layer by vacuum vapor deposition, and a 40-nm-thick film of aluminum quinolinol complex (Alq3) was formed thereover as an organic light emitting layer by vacuum vapor deposition. Finally a 40-nm-thick film of magnesium-silver alloy (MgAg) was formed by vacuum vapor deposition to fabricate an organic EL element.

In order to determine the effective work function of RuOₓ used as the high work function layer, the following capacitor was fabricated. A P-type Si substrate was heat treated in an oxygen atmosphere at 900° C. to fabricate a SiO₂ film. The thickness of the SiO₂ film was regulated by varying the heat treatment time so as to be 6, 8 or 12 nm.

Successively, a RuOₓ film was fabricated by using a sputtering method based on a RuOₓ target in an oxygen/Ar atmosphere with a sputtering power of 30 W, and then successively a 150-nm-thick ITO film was formed by using a sputtering method using an ITO target in an Ar atmosphere with a sputtering power of 150 W. By passing through a photolitho process, a capacitor having the ITO/RuOₓ film as an electrode was fabricated. The thickness of the RuOₓ film was regulated within a range from 0.3 nm to 10 nm by varying the sputtering time. Successively, by the capacity (C)-voltage (V) measurement, the flat band voltage (Vfb) was determined, and from the variation of the Vfb against the thickness of the SiO₂ film, the effective work function of the ITO/RuOₓ film was calculated.

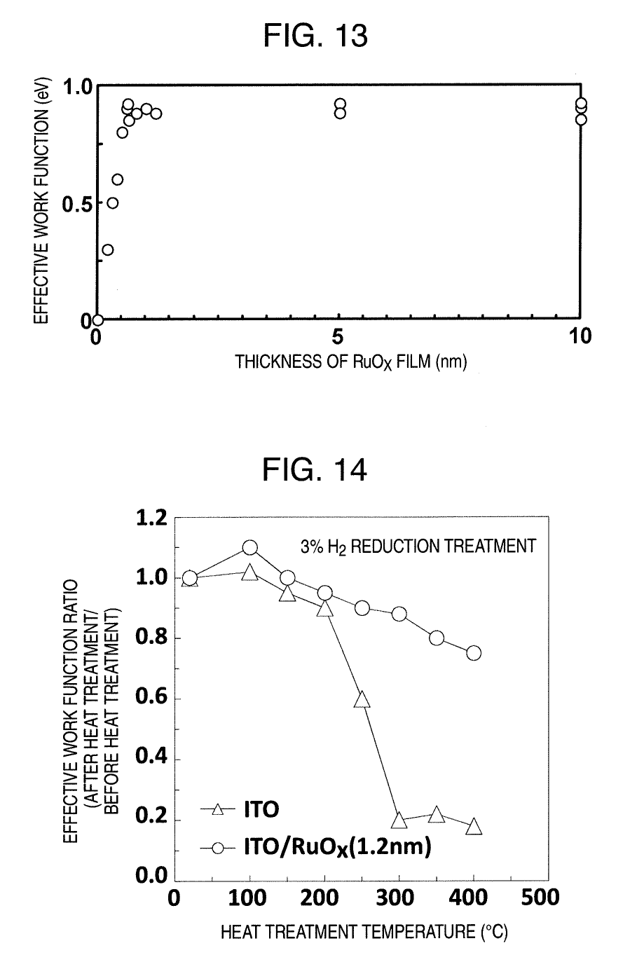

FIG. 13 shows the variation of the effective work function of the ITO/RuOₓ electrode against the thickness of the RuOₓ film. The ordinate of FIG. 12 represents the value obtained by subtracting the effective work function value obtained from the ITO/SiO₂/p-Si capacitor fabricated as a reference. The effective work function value was increased with the increase of the thickness of the RuOₓ layer interposed between the ITO film and the SiO₂ layer. In particular, it has been found that the effective function is steeply increased until the thickness reaches 0.6 nm, and the variation exhibits a tendency for being saturated at a thickness of at least 1.2 nm.

FIG. 14 shows a graph showing the variations of the effective work functions of the ITO film and the ITO/RuOₓ film respectively calculated from the VFb values when the ITO/SiO₂/p-Si capacitor and the ITO/RuOₓ(1.2 nm)/SiO₂/p-Si capacitor were treated by reduction for 30 minutes from 100° C. to 400° C. at intervals of 50° C. under a flow of 100 sccm of 3% H₂ gas.

The ordinate represents the value obtained by dividing the value of the effective work function after the heat treatment by the value of the effective work function before the heat treatment. The effective work function of the ITO film was steeply decreased from 250° C., and was varied at 300° C. to a small value reduced by a large decrement of approximately 0.8. Even when the heat treatment temperature was further increased, the same value was maintained to show that the decrease was saturated at 300° C. The major cause of the decrease of the effective work function is considered to be the elimination of oxygen from the ITO electrode due to the reduction treatment. On the other hand, the effective work function of the ITO/RuOₓ (1.2 nm) electrode exhibits a slow decrease with the increase of the reduction temperature; however, even at 400° C., the decrease of the work function is found to be suppressed to approximately 0.3. When compared with the ITO film at 300° C., the ITO/RuOₓ (1.2 nm) electrode exhibits the effective work function higher by approximately 0.7. This is probably because the RuOₓ film maintained the structural stability against the reduction, and consequently the elimination of oxygen from the ITO/RuOₓ (1.2 nm) film was suppressed.

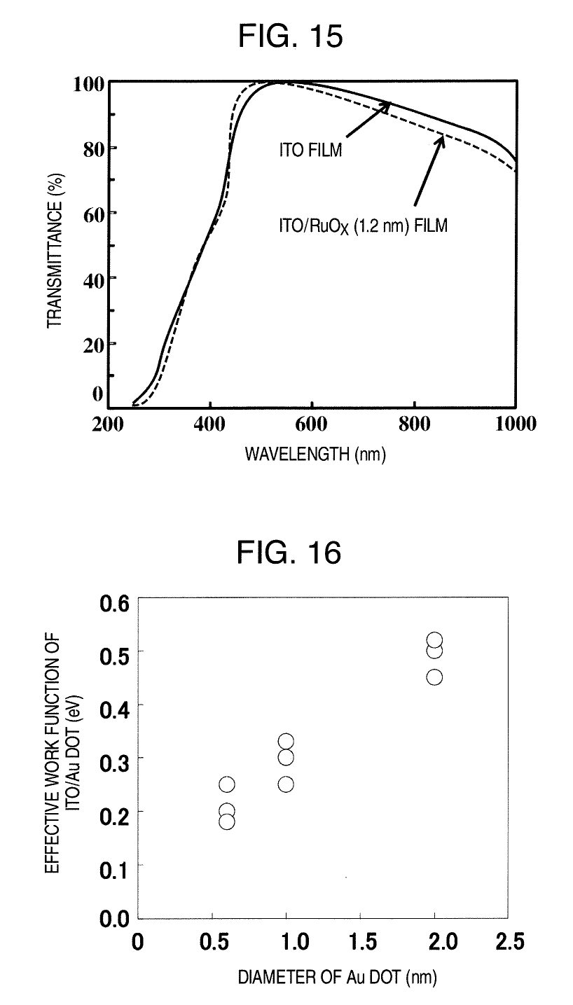

On a glass substrate, a 1.2-nm-thick RuOₓ film was formed, and then a 150-nm-thick ITO film was fabricated. For comparison, on a glass substrate, a 150-nm-thick ITO film was fabricated. FIG. 15 shows the variations of the transmission spectra of both of these films against the wavelength. The ordinate represents the difference obtained by subtracting the transmission spectrum of only the glass substrate. The profile of the transmittance of the ITO/RuOₓ (1.2 nm) film of the present invention against the wavelength exhibits a tendency for somewhat decreasing in a longer wavelength region of 700 nm or more as compared with the profile of the transmittance of the ITO film; however, the ITO/RuOₓ (1.2 nm) film maintains satisfactory transmission property in such a way that the value of the transmittance at 600 nm in the visible light region exhibits 90%.

Capacitors were fabricated in which a 1.2-nm-thick RuOₓ film was formed on SiO₂/p-Si, then by the sputtering method using IZO (In_{0.95}Zn_{0.05}O) and IWO (In_{0.99}W_{0.01}O) for targets in place of ITO, a 150-nm-thick IZO/RuOₓ(1.2 nm) electrode and a 150-nm-thick IWO/RuOₓ (1.2 nm) electrode were formed. The values of the effective work functions of both capacitors, calculated from the Vfb values exhibited both values higher by approximately 0.9 eV as compared with the value of the effective work function of the ITO electrode.

Moreover, by using an IrOₓ target and a Pt target in place of the RuOₓ target, a 1.2-nm-thick IrOₓ film and a 1.2-nm-thick Pt film were formed on SiO₂/p-Si, and then on each of these films, a 150-nm-thick film was formed, and thus capacitors were fabricated in which an ITO/IrOₓ (1.2 nm) electrode and an ITO/PtOₓ electrode were formed, respectively. Pt itself is well known as a hardly oxidizable material, but tends to take the PtOₓ structure including dissolved oxygen due to the oxygen atmosphere in the stage of forming the ITO film. The values of the effective work functions of both capacitors, calculated from the Vfb values were higher as compared with the value of the effective work function of the ITO electrode, and the values of the effective work functions of ITO/IrOₓ (1.2 nm) and ITO/PtOₓ exhibited values higher by approximately 1.1 eV and 0.9 eV, respectively. This is probably because the order of the magnitudes of the work functions of the RuOₓ, IrOₓ and PtOₓ materials is represented by RuOₓ,PtOₓ<IrOₓ, and this order affected the work functions.

### Example 5

FIG. 12 shows the structure of an example of the organic EL element of present invention. The organic EL element structure is also constituted by forming the following members on a glass substrate 201 used as a transparent substrate in the described order: a cathode 202 including dots 208, an organic hole transport layer 205, an organic light emitting layer 206 and an anode 207. A 150-nm thick ITO film was formed on the glass substrate by a 150-W high-frequency magnetron sputtering method using the ITO (In_{0.9}Sn_{0.1}O) target in an Ar gas atmosphere, successively Au dots were formed by a 50-W high-frequency magnetron sputtering method using an Au target in an Ar atmosphere, and consequently a cathode was formed. The diameters of the dots were regulated within a range from 0.6 nm to 2 nm, with a short sputtering time and by varying the degree of vacuum and the sputtering power of the sputtering apparatus. Under the conditions of long sputtering time and formation of thick films, not the shape of the independently distributed dots but the continuously extending films tended to be formed, and the diameters of the dots stable as dots in shape were 2 nm or less. Because dots are formed by aggregation of a plurality of extremely small sized nuclei formed on a substrate at the initial stage, the dots formed in this way have sizes of a certain order of magnitude or more; and hence the minimum diameter of the dots was 0.6 nm or more.

Moreover, the coverage of the dots (namely, [sum of areas projected to substrate of all dots placed on substrate]/[surface area of substrate]) depends on the diameters of the dots; when the diameter is 2 nm, the coverage is approximately 90%, and the coverage decreases with the decrease of the diameter. When dots are formed by using a sputtering method using Pt, Ir, Pd, Ni and Co for the target in place of Au, the diameter to maintain the dot shape is 0.6 nm or more and 2 nm or less.

Successively, a 40-nm-thick film of naphthyl phenyl benzidine (NPB) was formed as an organic hole transport layer by vacuum vapor deposition, and a 40-nm-thick film of aluminum quinolinol complex (Alq3) was formed thereover as an organic light emitting layer by vacuum vapor deposition. Finally a 40-nm-thick film of magnesium-silver alloy (MgAg) was formed by vacuum vapor deposition to fabricate an organic EL element.

In order to determine the effective work function of Au used as the dots, the following capacitor was fabricated. A P-type Si substrate was heat treated in an oxygen atmosphere at 900° C. to fabricate a SiO₂ film. The thickness of the SiO₂ film was regulated by varying the heat treatment time so as to be 6, 8 or 12 nm.

Successively, an Au film was fabricated by using a sputtering method based on an Au target in an Ar atmosphere with a sputtering power of 30 to 100 W, and then successively a 150-nm-thick ITO film was formed by using a sputtering method using an ITO target in an Ar atmosphere with a sputtering power of 150 W. By passing through a photolitho process, a capacitor having the ITO/Au dots as an electrode was fabricated. By varying the sputtering power, there were fabricated three different types of Au dots each having diameters falling in the vicinities of 0.6 nm, 1 nm and 2 nm, respectively. The shapes and the diameters of the dots were determined by the cross sectional observation using a transmission type electron microscope.

Successively, by the capacity (C)-voltage (V) measurement, the flat band voltage (Vfb) was determined, and from the variation of the Vfb against the thickness of the SiO₂ film, the effective work function of the ITO/Au dots was calculated.

FIG. 16 shows the variation of the effective work function of an ITO/Au dots electrode against the diameter of the Au dots. The ordinate represents the value obtained by subtracting the effective work function value obtained from the ITO/SiO₂/p-Si capacitor fabricated as a reference. With the increase of the diameter of the Au dots interposed between the ITO film and SiO₂ layer, the effective work function value increased. This cannot be ascribed to the effect of the diameter of Au dots on the effective work function, but can be ascribed to the significant involvement of the coverage of the Au dots on the plane. Specifically, this is because when the diameters of the Au dots are small, the occupancy rate of the projection to the SiO₂ layer (namely, the coverage of the dots) is also small, and when the diameter is 2 nm, the coverage increases to approximately 90%.

### Example 6

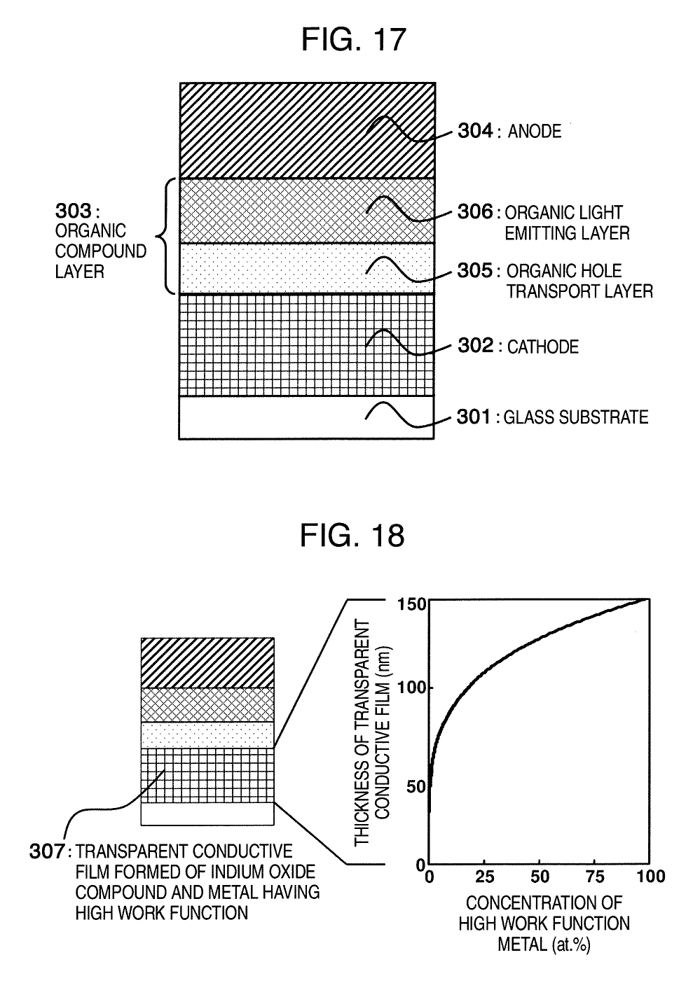

FIG. 17 shows the structure of the organic EL element of an example of the present invention. On a glass substrate 301 to be used as a transparent substrate, a cathode 302, an organic compound layer 303, and an anode 304 are formed in this order; the organic compound layer 303 is constituted with an organic hole transport layer 305 and an organic light emitting layer 306 from the side of the cathode 302. In an example of the present invention, the cathode 302 is a transparent electrode film constituted with an indium oxide compound and a metal having a high work function. FIG. 18 shows a schematic diagram of the structure of the transparent conductive film 307, and the concentration gradient of the metal in the transparent conductive film 307. The transparent conductive film 307 was formed in such a way that as approaching the side of the organic hole transport layer 305, the concentration of the metal having a high work function was increased. Owing to such a concentration gradient, the concentration of the metal having a high work function varies only in the transparent conductive film to serve as a base material, accordingly there is no steep interface and the variation of the refractive index is small, and consequently the decrease of the transmittance can also be made small.

The formation of the transparent electrode film having this concentration gradient was performed as follows. The transparent conductive film 307 was formed on the glass substrate 301 by using a co-sputtering method based on an ITO (In_{0.9}Sn_{0.1}O) target and a Pt target; specifically, by varying the sputtering powers for ITO and Pt, the ITO (ITO:Pt) film having Pt was formed so as to have a total thickness of 150 nm. In this connection, at the initial stage of the film formation, a 100-nm-thick pure ITO film was formed by applying only an ITO sputtering power of 150 W. Successively, as the sputtering power for Pt was increased from 5 W to 150 W, the sputtering power for ITO was decreased from 150 W to 0 W, and thus, a 50-nm-thick layer was formed.

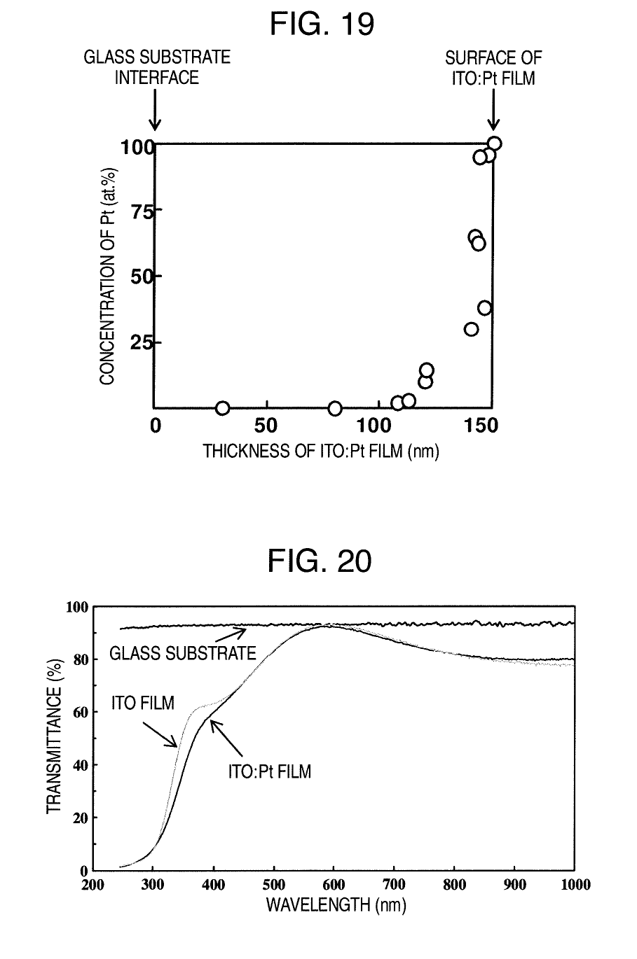

The concentration profile of the composition ratio of the ITO:Pt film in the thickness direction was measured by the Pt4f and In3d XPS measurements while an Ar etching was being performed from the surface of the ITO:Pt film. FIG. 19 shows the relation between the Pt concentration (Pt/(Pt+In)) and the position (namely, the distance from the surface of the glass substrate) in the ITO:Pt film in the direction perpendicular to the film surface as the results of the measurement (in FIG. 19, the abscissa is denoted as “Thickness of ITO:Pt film”; this thickness represents the thickness of the residual film during the partial removal of the film by the foregoing Ar etching, and is equivalent to the distance of the measurement point from the substrate surface). As can be seen from FIG. 18, the Pt concentration was 100 at. % on the uppermost surface (the surface on the side of the organic compound layer) of the ITO:Pt film, the Pt concentration exhibited a tendency for decreasing from the film surface toward the side of the glass substrate, and the Pt concentration was 0 in the range from 0 to the vicinity of 100 nm.

FIG. 20 shows the transmission spectra against wavelength of the glass substrate, the ITO film and the ITO:Pt film, against wavelength. The profile of the transmittance against wavelength of the ITO:Pt film of the present example exhibited the same tendency as in the ITO film. The transmittance at 600 nm in the visible light region exhibits 90%, almost equal to the value for the glass substrate, and thus, the decrease of the transmittance due to the ITO:Pt film is not found.

Successively, a 40-nm-thick film of naphthyl phenyl benzidine (NPB) was formed as an organic hole transport layer by vacuum vapor deposition, and a 40-nm-thick film of aluminum quinolinol complex (Alq3) was formed thereover as an organic light emitting layer by vacuum vapor deposition. Finally a 40-nm-thick film of magnesium-silver alloy (MgAg) was formed by vacuum vapor deposition to fabricate an organic EL element.

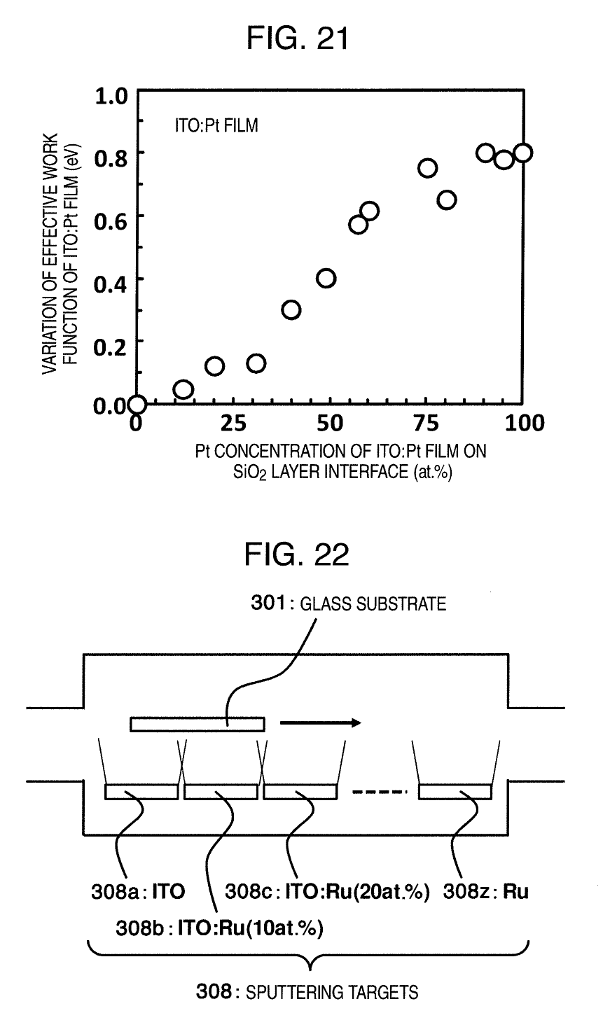

In order to determine the effective work function of the ITO:Pt film, the following capacitor was fabricated. A P-type Si substrate was heat treated in an oxygen atmosphere at 900° C. to fabricate a SiO₂ film. The thickness of the SiO₂ film was regulated by varying the heat treatment time so as to be 6, 8 or 12 nm. Successively, by using the co-sputtering method based on the ITO target and the Pt target, a 150-nm-thick ITO:Pt gate electrode was fabricated by a lift-off process to fabricate a capacitor. By varying the sputtering power of each of the targets of the co-sputtering, the Pt concentration of the uppermost surface of the ITO:Pt film was controlled within a range of 0 to 100 at. %. Successively, by the capacity (C)-voltage (V) measurement, the flat band voltage (Vfb) was calculated, and from the variation of the Vfb against the thickness of the SiO₂ film, the effective work function was determined FIG. 21 shows the variation of the effective work function of an ITO:Pt electrode against the Pt concentration of an ITO:Pt film on the SiO₂ layer interface (at. %). The ordinate represents the value (the variation of the effective work function, namely, the increment) obtained by subtracting the effective work function value obtained from the ITO/SiO₂/p-Si capacitor fabricated as a reference. The effective work function was increased by 0.05 eV even for the Pt concentration of 12 at. %, and exhibited a tendency for increasing with the increase of the Pt concentration. It has been found that when the Pt concentration of the ITO:Pt film is 60 at. % or more, the increase effect of the effective work function of 0.5 eV or more is obtained.

### Example 7

In an example of the present invention, as shown in FIG. 22, an ITO:Ru film was formed on a glass substrate 301 by using a sputtering method based on sputtering targets arranged consecutively. In the sputtering targets, the Ru concentration was increased in the order of the targets of ITO 308a at the initial stage, and consecutively ITO:Ru (10 at. %) 308b, ITO:Ru (20 at. %) 308c and so on, and at the final stage, a target of Ru 308z was arranged. By varying the sputtering power and the film formation time for each of the targets, the film thickness was regulated, and finally there was formed an ITO:Ru film having a Ru concentration gradient in which the Ru concentration increased from the side of the glass substrate toward the organic hole transport layer. By increasing the number of the targets having finely varied Ru concentrations, the concentration gradient of Ru is preferably further smoothly varied. Successively, a 40-nm-thick film of naphthyl phenyl benzidine (NPB) was formed as an organic hole transport layer by vacuum vapor deposition, and a 40-nm-thick film of aluminum quinolinol complex (Alq3) was formed thereover as an organic light emitting layer by vacuum vapor deposition. Finally a 40-nm-thick film of magnesium-silver alloy (MgAg) was formed by vacuum vapor deposition to fabricate an organic EL element.

The same effect can also be obtained by fabricating, on the indium oxide compound, a transparent conductive film having, as metals having high work functions, Ir, Pd, Ni, Au or Co metal other than Pt and Ru, with optimal sputtering powers for these metals. In this connection, the use of alloys composed of two or more metals is preferable with respect to the structural stability.

The indium oxide compound is represented by InₓMe₁₋ₓO_{y}, typical examples of the Me element include, as described above, Sn, Zn and W, and examples of the elements alternative to these elements include one or more types of elements selected from the elements of Group IVa, Group Va, Group IVb and Group Vb. When among these, Ti, Zr, Hf, V, Nb, Ta, Si and Sb elements are used, the miscibility of the foregoing elements with the above-described elements having high work functions is satisfactory, and excellent structural stability is exhibited. The substitution rate of the Me element falls preferably within a range of x larger than 0 and smaller than 0.5, in consideration of the tendency that the substitution decreases the conductivity and the transmittance. In particular, when InₓSn₁₋ₓO_{y}, InₓZn₁₋ₓO_{y}, InₓW₁₋ₓO_{y} and InₓSi₁₋ₓO_{y} are used as the indium oxide compound, the substitution rate preferably falls within a range of y larger than 1.25 and smaller than 1.5, larger than 1.25 and smaller than 1.5, larger than 1.5 and smaller than 2.25, and larger than 1.5 and smaller than 1.75, respectively, because low resistance values are obtained.

From the above-described results, the operation of the organic EL element of the present invention has been able to be verified and the usefulness of the present invention has been verified.

The foregoing description has been made on the examples; however, the present invention is not limited to these examples, and it is apparent for a person skilled in the art that the present invention can be variously altered and modified within the scope of the spirit of the present invention and the appended claims.

### INDUSTRIAL APPLICABILITY

As described above, according to the present invention, it is possible to realize a cathode formed of a transparent conductive film, having a high work function while a satisfactory transmittance for visible light and a satisfactory conductivity are being maintained; thus the present invention can significantly contribute to the improvement of the performances of the organic EL element.

1. An organic EL element comprising:
a transparent substrate;
a cathode formed on the transparent substrate;
a one or more-layered organic compound layer formed on the cathode; and
an anode formed on the organic compound layer,
wherein the cathode is a transparent conductive film including an indium oxide compound and a noble metal element-containing conductive oxide.

2. The organic EL element according to claim 1,
wherein the transparent conductive film comprises:
a first transparent conductive film being disposed on a side of the transparent substrate, including the indium oxide compound but not including the noble metal element; and
a second transparent conductive film being disposed on a side of the organic compound layer and including the indium oxide compound and the noble metal element.

3. The organic EL element according to claim 1, wherein an addition amount of the noble metal element of the noble metal element-containing conductive oxide falls within a range larger than 0 at. % and smaller than 50 at. % in relation to a total amount of the noble metal element and an indium element of the indium oxide compound.

4. The organic EL element according to claim 1, wherein the noble metal element-containing conductive oxide consists of one conductive oxide or a combination of two or more conductive oxides selected from the group consisting of PtOₓ, IrOₓ and RuOₓ.

5. The organic EL element according to claim 1, wherein the noble metal element-containing conductive oxide is SrRuOₓ.

6. The organic EL element according to claim 1,
wherein the indium oxide compound is represented by the following chemical formula:
InₓMe₁₋ₓO_{y},
wherein Me is one or more elements selected from the group consisting of elements of the Group IVa, Group Va, Group IVb and Group Vb, and
0<x<0.5 and 1.0<y<2.0.

7. The organic EL element according to claim 1, wherein the indium oxide compound is one or more compounds selected from the group consisting of:
InₓSn₁₋ₓO_{y} (1.25<y<1.5),
InₓZn₁₋ₓO_{y} (1.25<y<1.5),
InₓW₁₋ₓO_{y} (1.5<y<2.25) and
InₓSi₁₋ₓO_{y} (1.5<y<1.75),
wherein 0<x<0.5.

8. A method of manufacturing the organic EL element according to claim 1, comprising forming the transparent conductive film by a co-sputtering method,
wherein the co-sputtering method comprises regulating a sputtering power ratio between the indium oxide compound and the noble metal element-containing conductive oxide, wherein the transparent conductive film controlled in a composition ratio between the indium oxide compound and the noble metal element-containing conductive oxide is formed.

9. A method of manufacturing the organic EL element according to claim 1, comprising:
forming the transparent conductive film by co-sputtering the indium oxide compound and a metal of the noble metal element,
wherein an oxygen composition ratio of the transparent conductive film is controlled by subjecting the transparent conductive film to ozone and/or plasma oxidation treatment.

10. The organic EL element according to claim 1,
wherein the transparent conductive film comprises:
a first transparent conductive film being disposed on the side of the transparent substrate, and including the indium oxide compound, and
a second transparent conductive film being disposed on the side of the organic compound layer, and including indium oxide and the noble metal element-containing conductive oxide.

11. The organic EL element according to claim 10, wherein the second transparent conductive film is an amorphous structure.

12. The organic EL element according to claim 11, wherein a thickness of the second transparent conductive film is 4 nm or less.

13. The organic EL element according to claim 11, wherein the addition amount of the noble metal element of the noble metal element-containing conductive oxide is regulated so as for a work function of the second transparent conductive film to be 5 eV or more.

14. The organic EL element according to claim 11, wherein the addition amount of the noble metal element of the noble metal element-containing conductive oxide falls within a range larger than 20 at. % and smaller than 70 at. % in relation to the total amount of the noble metal element and the indium element of the indium oxide.

15. The organic EL element according to claim 10, wherein the noble metal element-containing conductive oxide consists of one conductive oxide or a combination of two or more conductive oxides selected from the group consisting of PtOₓ, IrOₓ and RuOₓ.

16. The organic EL element according to claim 10, wherein the noble metal element-containing conductive oxide is SrRuOₓ.

17. The organic EL element according to claim 10, wherein the indium oxide compound is represented by the following chemical formula:
InₓMe₁₋ₓO_{y},
wherein Me is one or more elements selected from the group consisting of the elements of the Group IVa, Group Va, Group IVb and Group Vb, and
0<x<0.5 and 1.0<y<2.0.

18. The organic EL element according to claim 10, wherein the indium oxide compound is one or more compounds selected from the group consisting of:
InₓSn₁₋ₓO_{y} (1.25<y<1.5),
InₓZn₁₋ₓO_{y} (1.25<y<1.5),
InₓW₁₋ₓO_{y} (1.5<y<2.25) and
InₓSi₁₋ₓO_{y} (1.5<y<1.75),
wherein 0<x<0.5.

19. A method of manufacturing the organic EL element according to claim 10, comprising forming the second transparent conductive film by a co-sputtering method,
wherein the co-sputtering method comprises regulating a sputtering power ratio between the indium oxide and the noble metal element, wherein the second transparent conductive film controlled in the composition ratio between the indium oxide and the noble metal element-containing conductive oxide is formed.

20. An organic EL element comprising:
a transparent substrate;
a cathode formed on the transparent substrate;
a one or more-layered organic compound layer formed on the cathode; and
an anode formed on the organic compound layer,
wherein the cathode is a transparent conductive film including:
(i) a high work function layer formed of a material having a work function higher than 5 eV and having a thickness of 0.6 nm or more and 1.2 nm or less; or
(ii) a plurality of particles formed of a material having a work function higher than 5 eV.

21. (canceled)

22. The organic EL element according to claim 20, wherein particle sizes of the particles are 0.6 nm or more and 2 nm or less.

23. The organic EL element according to claim 20,
wherein the material having a work function higher than 5 eV, which forms either the high work function layer or the plurality particles, is one material or a combination of two or more materials selected from the group consisting of PtOₓ, IrOₓ and RuOₓ.

24. The organic EL element according to claim 20,
wherein the material having a work function higher than 5 eV, which forms either the high work function layer or the plurality of particles, is one element or an alloy of two or more elements selected from the group consisting of Pt, Ir, Pd, Ni, Au and Co.

25. The organic EL element according to claim 20,
wherein a material of the cathode is an indium oxide compound represented by the following formula:
InₓMe₁₋ₓO_{y}
wherein Me is one or more elements selected from the group consisting of the elements of the Group IVa, Group Va, Group IVb and Group Vb, and
0<x<0.5 and 1.0<y<2.0.

26. The organic EL element according to any one of claim 25,
wherein the indium oxide compound is one or more compounds selected from the group consisting of:
InₓSn₁₋ₓO_{y} (1.25<y<1.5),
InₓZn₁₋ₓO_{y} (1.25<y<1.5),
InₓW₁₋ₓO_{y} (1.5<y<2.25) and
InₓSi₁₋ₓO_{y} (1.5<y<1.75),
wherein 0<x<0.5.

27. An organic EL element comprising:
a transparent substrate;
a cathode formed on the transparent substrate;
a one or more-layered organic compound layer formed on the cathode; and
an anode formed on the organic compound layer,
wherein the cathode includes a transparent conductive film including an indium oxide compound and a metal having a high work function; and
the metal being included in the transparent conductive film and having a high work function, has a concentration gradient from the side of the transparent substrate toward the side of the organic compound.

28. The organic EL element according to claim 27, wherein a concentration of the metal being included in the transparent conductive film and having a high work function, is higher in a region of the organic compound layer than in a region on the side of the transparent substrate.

29. The organic EL element according to claim 27, wherein the metal having a high work function is one or more elements selected from Pt, Ir, Pd, Ni, Ru, Au and Co.

30. The organic EL element according to claim 27, wherein the concentration of the metal having a high work function is 60 at. % or more and 100 at. % or less in a region on the side of the organic compound layer.

31. The organic EL element according to claim 27,
wherein the indium oxide compound is represented by the following formula:
InₓMe₁₋ₓO_{y}
wherein Me is one or more elements selected from the group consisting of the elements of the Group IVa, Group Va, Group IVb and Group Vb, and
0<x<0.5 and 1.0<y<2.0.

32. The organic EL element according to claim 27,
wherein the indium oxide compound is one or more compounds selected from the group consisting of:
InₓSn₁₋ₓO_{y} (1.25<y<1.5),
InₓZn₁₋ₓO_{y} (1.25<y<1.5),
InₓW₁₋ₓO_{y} (1.5<y<2.25) and
InₓSi₁₋ₓO_{y} (1.5<y<1.75),
wherein 0<x<0.5.

33. A method of manufacturing the organic EL elements according to claim 27, comprising forming the transparent conductive film by a sputtering method,
wherein the sputtering method comprises controlling a sputtering power ratio between the indium oxide compound and the metal having a high work function, wherein the transparent conductive film having a concentration gradient of the metal having a high work function is formed.

34. A method of manufacturing the organic EL elements according to claim 27, comprising forming the transparent conductive film by a sputtering method,
wherein the sputtering method comprises:
arranging a plurality of targets varied in a composition ratio between the indium oxide compound and the metal having a high work function, and
forming the transparent conductive film by using a sputtering method consecutively using the plurality of targets, wherein the transparent conductive film having the concentration gradient of the metal having a high work function is formed.
